(19) United States
(12) Patent Application Publication
(10) Pub. No.: US 2025/0273644 A1
(43) Pub. Date: Aug. 28, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Seungwoo Sim, Suwon-si (KR); Sangyoung Kim, Suwon-si (KR); Jongpa Hong, Suwon-si (KR); Dongjoo Choi, Suwon-si (KR)

(73) Assignee: SAMSUNG ELECTRONICS CO., LTD., Suwon-si (KR)

(21) Appl. No.: 18/974,311

(22) Filed: Dec. 9, 2024

(30) Foreign Application Priority Data
Feb. 26, 2024 (KR) 10-2024-0027366

(51) Int. Cl. H01L 25/18; H01L 23/00; H01L 25/00; H10B 80/00

(52) U.S. Cl. CPC H01L 25/18; H01L 24/13; H01L 24/14; H01L 24/16; H01L 24/32; H01L 24/73; H01L 24/81; H01L 25/50; H01L 2224/13014; H01L 2224/13147; H01L 2224/1357; H01L 2224/14051; H01L 2224/16145; H01L 2224/16225; H01L 2224/32145; H01L 2224/32225; H01L 2224/73204; H01L 2224/81815; H01L 2225/06513; H01L 2225/06541; H01L 2924/1431; H01L 2924/14361; H01L 2924/20751; H01L 2924/37001; H10B 80/00

(57) ABSTRACT

A semiconductor package includes a buffer die; a plurality of core dies sequentially stacked on the buffer die via conductive bumps; and a plurality of adhesive layers between the plurality of core dies, the plurality of adhesive layers filling spaces between the conductive bumps and interconnecting the plurality of core dies; wherein each of the core dies of the plurality of core dies includes a middle region and diagonal regions that extend from the middle region to four corner portions of a respective core die, and wherein the conductive bumps includes: a plurality of first bump structures in the middle region, each first bump structure having a circular shape; and a plurality of second bump structures in each of the diagonal regions, each second bump structure having an elliptical shape.

### CROSS-REFERENCE TO RELATED APPLICATION

This application claims priority under 35 U.S.C. § 119 to Korean Patent Application No. 10-2024-0027366, filed on Feb. 26, 2024 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of different stacked chips and a method of manufacturing the same.

### 2. Description of the Related Art

Recently, electronic devices may include a high bandwidth memory (HBM) or a stacked chip package to provide high performances such as a high capacitance and a high speed operation. In manufacturing the HBM memory devices used in such an electronic device, a plurality of semiconductor chips may be vertically bonded on one another using an adhesive film. In the bonding process of the semiconductor chips, the adhesive film having fluidity may flow from a middle region to an edge region, wherein the adhesive film may be cured to fill spaces between the semiconductor chips. However, after the curing, the adhesive film may not be sufficiently filled in chip corners that are relatively far away, thereby lowering the yield.

### SUMMARY

Example embodiments provide a semiconductor package having conductive bumps that is able to improve bonding quality.

Example embodiments provide a method of manufacturing the semiconductor package.

According to an aspect of the disclosure, a semiconductor package, including: a buffer die; a plurality of core dies sequentially stacked on the buffer die via conductive bumps; and a plurality of adhesive layers between the plurality of core dies, the plurality of adhesive layers filling spaces between the conductive bumps and interconnecting the plurality of core dies; wherein each of the core dies of the plurality of core dies comprises a middle region and diagonal regions that extend from the middle region to four corner portions of a respective core die, and wherein the conductive bumps includes: a plurality of first bump structures in the middle region, each first bump structure having a circular shape; and a plurality of second bump structures in each of the diagonal regions, each second bump structure having an elliptical shape.

According to an aspect of the disclosure, a semiconductor package includes: a first semiconductor chip; a second semiconductor chip; a third semiconductor chip; a fourth semiconductor chip; and a plurality of adhesive layers, wherein the first semiconductor chip, the second semiconductor chip, the third semiconductor chip, and the fourth semiconductor chip are sequentially stacked using conductive bumps, wherein the plurality of adhesive layers are between the first semiconductor chip, the second semiconductor chip, the third semiconductor chip, and the fourth semiconductor chip, the plurality of adhesive layers filling spaces between the conductive bumps and interconnecting the first semiconductor chip, the second semiconductor chip, the third semiconductor chip, and the fourth semiconductor chip, wherein each of the first semiconductor chip, the second semiconductor chip, the third semiconductor chip, and the fourth semiconductor chip comprises (i) a substrate having a first surface and a second surface opposite to the first surface, and (ii) first bonding pads provided on the first surface of the substrate, wherein each of the first semiconductor chip, the second semiconductor chip, the third semiconductor chip, and the fourth semiconductor chip has a middle region and diagonal regions that extend from the middle region to four corner portions of a respective semiconductor chip, and wherein the conductive bumps include: a plurality of first bump structures on the first bonding pads in the middle region, each first bump structure having a circular shape, and a plurality of second bump structures on the first bonding pads in each of the diagonal regions, each second bump structure having an elliptical shape.

According to an aspect of the disclosure, a semiconductor package includes: a first semiconductor chip comprising (i) a first substrate having a first surface and a second surface opposite the first surface, (ii) a plurality of first through electrodes penetrating the first substrate, and (iii) a plurality of first bonding pads provided on the second surface and electrically connected to the plurality of first through electrodes; a second semiconductor chip stacked on the second surface of the first semiconductor chip, the second semiconductor chip comprising (i) a second substrate having a third surface that faces the second surface and a fourth surface opposite to the third surface, and (ii) a plurality of second bonding pads on the third surface to respectively correspond to the plurality of first bonding pads; a plurality of conductive bumps interposed between the plurality of first bonding pads and the corresponding plurality of second bonding pads; and an adhesive layer between the first semiconductor chip and the second semiconductor chip, the adhesive layer filling spaces between the conductive bumps and interconnecting the first semiconductor chip and the second semiconductor chip, wherein the second substrate of the second semiconductor chip has diagonal regions that extend from a middle region to four corner portions of the second semiconductor chip, wherein the plurality of conductive bumps comprise bump structures on the plurality of second bonding pads in each of the diagonal regions, each bump structure having an elliptical shape, and wherein the bump structures are arranged such that longitudinal axes of the bump structures extend toward the middle region.

### BRIEF DESCRIPTION OF DRAWINGS

Example embodiments will be more clearly understood from the following detailed description taken in conjunction with the accompanying drawings. FIGS. 1 to 26 represent non-limiting, example embodiments as described herein.

FIG. 1 is a cross-sectional view illustrating an electronic device in accordance with example embodiments.

FIG. 2 is a cross-sectional view illustrating a semiconductor package in accordance with example embodiments.

FIG. 3 is an enlarged cross-sectional view illustrating portion ‘A’ in FIG. 2.

FIG. 4 is an enlarged cross-sectional view illustrating portion ‘B’ in FIG. 2.

FIG. 5 is a plan view illustrating conductive bumps on a first semiconductor chip of FIG. 2 in accordance with example embodiments.

FIG. 6 is an enlarged plan view illustrating portion ‘D’ in FIG. 5 in accordance with example embodiments.

FIG. 7 is a perspective view of FIG. 6 in accordance with example embodiments.

FIGS. 8 to 25 are views illustrating a method of manufacturing a semiconductor package in accordance with example embodiments.

FIG. 26 is a graph showing a change in flow resistance coefficient according to a ratio of long and short axes of a non-conductive film around an oval conductive bump.

### DETAILED DESCRIPTION

Hereinafter, example embodiments will be explained in detail with reference to the accompanying drawings.

It is to be understood that both the foregoing general description and the following detailed description are exemplary, and it is to be considered that an additional description of the claimed embodiments is provided. Reference signs are indicated in detail in preferred embodiments of the present embodiments, examples of which are indicated in the reference drawings. Wherever possible, the same reference numbers are used in the description and drawings to refer to the same or like parts.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

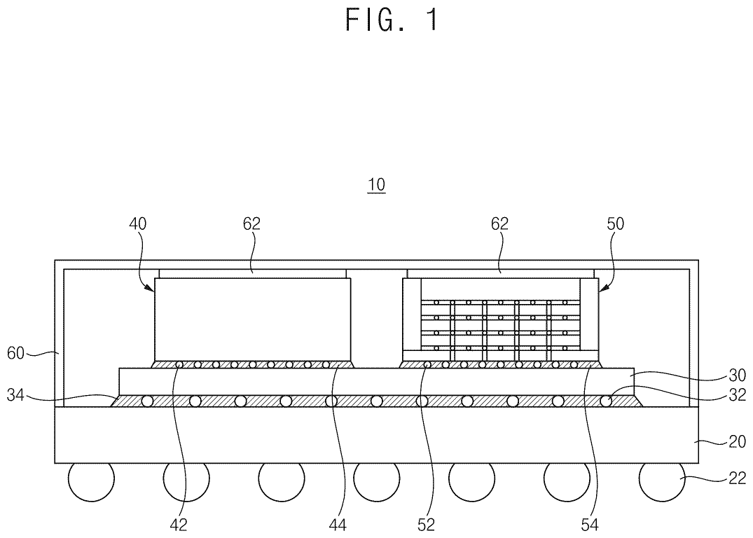

FIG. 1 is a cross-sectional view illustrating an electronic device in accordance with example embodiments.

Referring to FIG. 1, an electronic device 10 may include a substrate 20, an interposer 30, a first semiconductor device 40 and a second semiconductor device 50. In one or more examples, the electronic device 10 may further include first underfill members 44 and 54 and second underfill member 34, and a heat slug 60.

In example embodiments, the electronic device 10 may be a memory module having a stacked chip structure in which a plurality of dies (chips) are stacked. For example, the electronic device 10 may include a semiconductor memory device having a 2.5D chip structure. The electronic device 10 including the 2.5D chip structure memory device may include the interposer 30 for electrically connecting the first and second semiconductor devices (electronic components) 40 and 50 to each other. In one or more examples, a 2.5D chip structure may combine multiple integrated circuit dies in a single package without stacking the integrated circuit dies into a three-dimensional (3D) integrated circuit with through-silicon vias.

In one or more examples, the first semiconductor device 40 may include a logic semiconductor device, and the second semiconductor device 50 may include a memory device. The logic semiconductor device may be an ASIC as a host such as a CPU, GPU, or SOC. The memory device may include a high bandwidth memory (HBM) device.

In example embodiments, the substrate 20 may be a substrate having an upper surface and a lower surface facing each other. For example, the substrate 20 may be a printed circuit board (PCB). The printed circuit board may be a multi-layer circuit board having vias and various circuits therein.

The interposer 30 may be disposed on the substrate 20. The interposer 30 may be mounted on the substrate 20 through solder bumps 32. A planar area of the interposer 30 may be smaller than a planar area of the substrate 20. When viewed from a plan view, the interposer 30 may be disposed within an area of the substrate 20. As understood by one of ordinary skill in the art, the plan view may be a view of an object from the top.

The interposer 30 may be a silicon interposer or a redistribution wiring interposer having a plurality of wirings formed therein. The first semiconductor device 40 and the second semiconductor device 50 may be connected to each other through the wirings in the interposer 30 or electrically connected to the substrate 20 through the solder bumps 32. The silicon interposer may provide a high-density interconnection between the first and second semiconductor devices 40 and 50.

In example embodiments, the first semiconductor device 40 may be disposed on the interposer 30. The first semiconductor device 40 may be mounted on the interposer 30 by a flip chip bonding method. In one or more examples, the first semiconductor device 40 may be mounted on the interposer 30 such that an active surface on which chip pads are formed faces the interposer 30. The chip pads of the first semiconductor device 40 may be electrically connected to bonding pads of the interposer 30 by conductive bumps 42. For example, the conductive bumps may include micro bumps (uBumps). In one or more examples, the flip chip bonding method may include interconnecting semiconductor devices to external circuitry with solder bumps deposited on chip pads. To mount the chip to external circuitry, the chip may be flipped over so that the a top side of the chip faces down and aligned so that the pads of the chip match the pads of the external circuit, where solder may be reflowed to complete the interconnect.

The second semiconductor device 50 may be disposed on the interposer 30 to be spaced apart from the first semiconductor device 40. The second semiconductor device 50 may be mounted on the interposer 30 by the flip chip bonding method. In one or more examples, bonding pads of the second semiconductor device 50 may be electrically connected to bonding pads of the interposer 30 by conductive bumps 52. For example, the conductive bumps 52 may include micro bumps (uBumps).

Although one first semiconductor device 40 and one second semiconductor device 50 are illustrated to be disposed, it will be appreciated that the embodiments are not limited to these configurations.

In example embodiments, the first underfill members 44 and 54 may be underfilled between the first semiconductor device 40 and the interposer 30 and between the second semiconductor device 50 and the interposer 30, respectively. The second underfill member 34 may be underfill between the interposer 30 and the substrate 20.

The first and second underfill members may include a material having relatively high fluidity to effectively fill small spaces between the first and second semiconductor devices and the interposer and between the interposer and the substrate. For example, the first and second underfill members may include an adhesive containing an epoxy material. For example, the underfill members may be an epoxy-based material that connects a chip to a board by flowing into the gap between them. The underfill members may provide mechanical reinforcement to solder joints, which can increase the life of the chip. The underfill members may also act as a cushion layer during thermal cycling, protecting the solder joints from damage. The underfill members may also improve dropping performance and thermal cycling performance for components like Flip Chip (FC), Chip-Scale Packages (CSP), and Wafer Level Chip Scale Packages (WLCSP).

In example embodiments, the heat slug 60 may cover the substrate 20 to thermally contact the first and second semiconductor devices 40 and 50. Thermal interface materials (TIMs) 62 may be provided on upper surfaces of the first and second semiconductor devices 40 and 50, respectively. The heat slug 60 may be disposed to thermally contact the first and second semiconductor devices 40 and 50 via the thermal interface materials 62.

External connection pads may be formed on the lower surface of the substrate 20, and external connection members 22 may be disposed on the external connection pads for electrical connection with external devices. For example, the external connection member 22 may be a solder ball. The electronic device 10 may be mounted on a module board via the solder balls to form a memory module.

In example embodiments, the second semiconductor device 50 may include a buffer die and a plurality of the memory dies (chips) sequentially stacked on the buffer die. The buffer die and the memory dies may be electrically connected to each other by through silicon vias (TSVs). The through silicon vias may be electrically connected to each other by conductive bumps. The buffer die and the memory die may communicate data signals and control signals through the through silicon vias. In one or more examples, the buffer dies may function to repeat signals/data, and may further function to improve the performance of devices with a higher number of memory dies.

The electronic device 10 may include the high bandwidth memory (HBM) or a multi-chip package to provide high performance such as high capacity and high speed operation.

As will be described later, the second semiconductor device 50 may include conductive bumps for signal transmission between the stacked chips and adhesive layers between the stacked chips to fill spaces between the conductive bumps to attach the stacked chips. The conductive bumps may include first bump structures having a circular shape and second bump structures having an elliptical shape when viewed in plan view. The elliptical shapes of the second bump structures may prevent the adhesive layer from being underfilled at the corner of the chip. Thus, the yield in bonding processes of the HBM package may be improved.

Hereinafter, the HBM package device of FIG. 1 will be described.

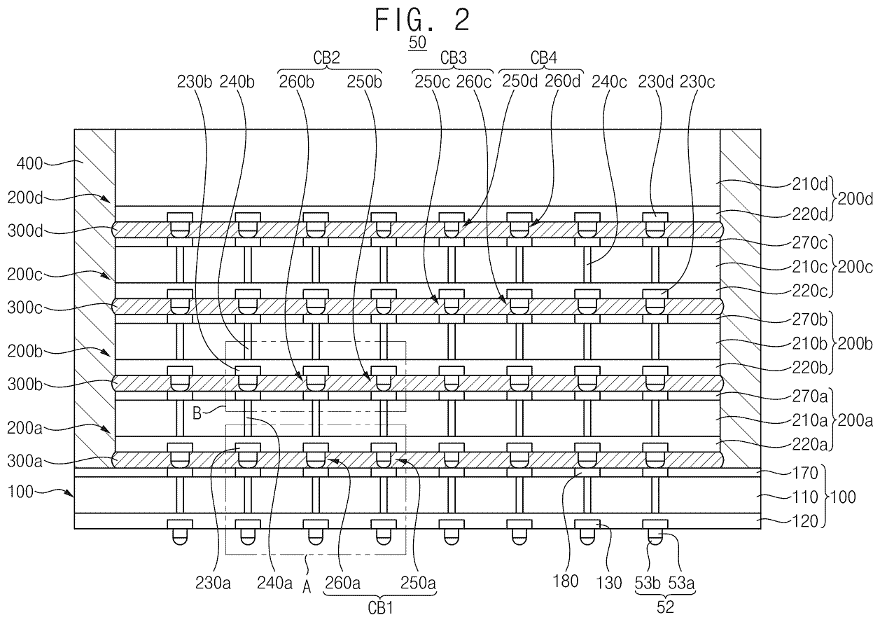

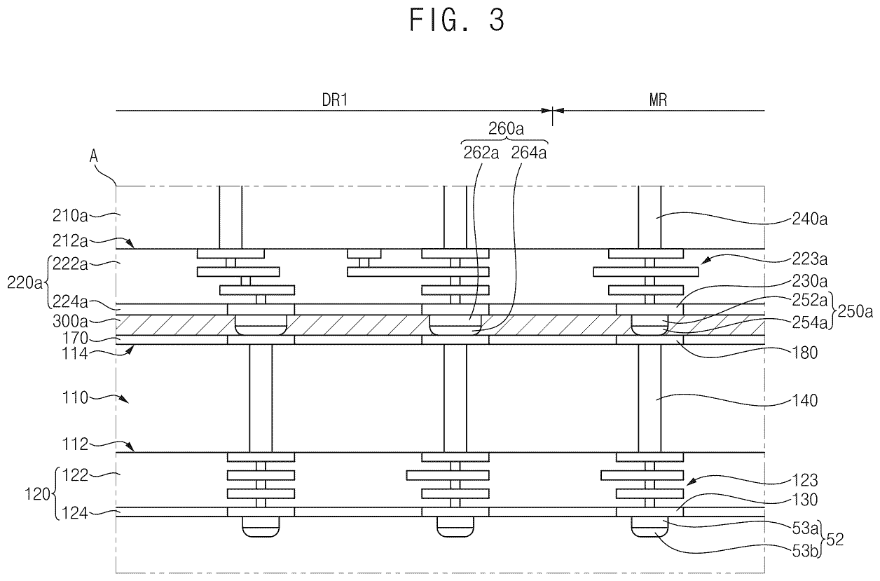

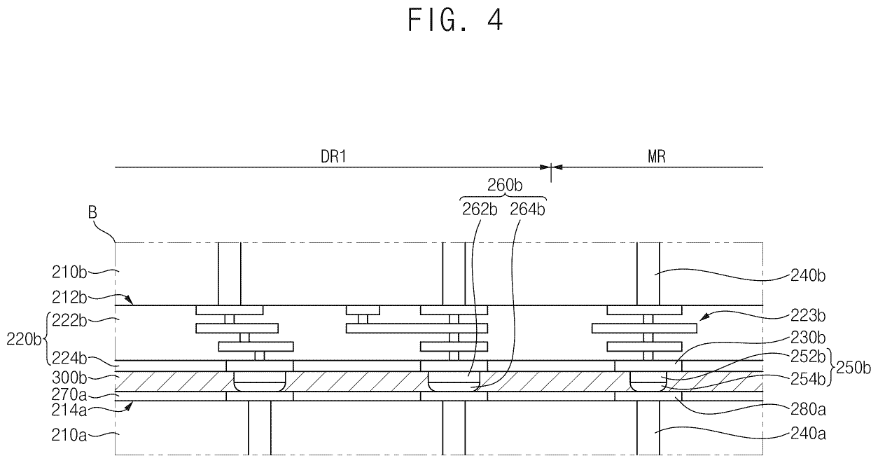

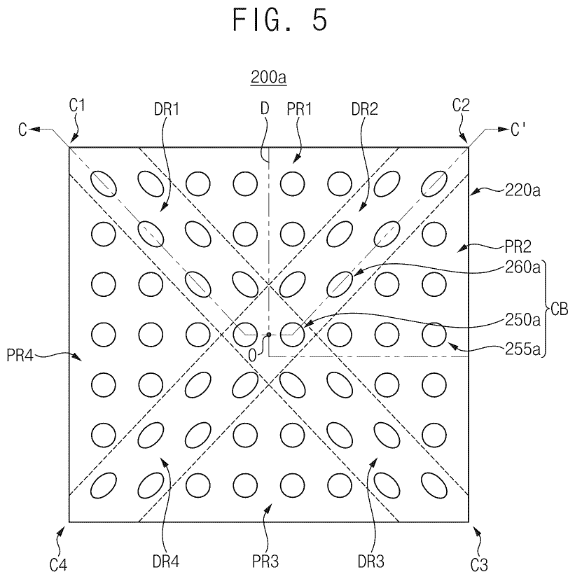

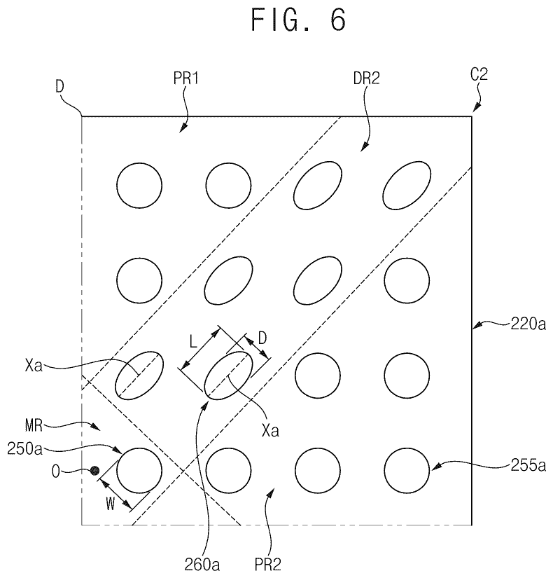

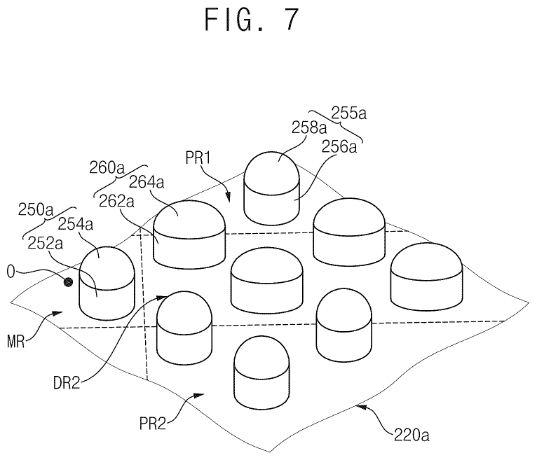

FIG. 2 is a cross-sectional view illustrating a semiconductor package in accordance with example embodiments. FIG. 3 is an enlarged cross-sectional view illustrating portion ‘A’ in FIG. 2 in accordance with example embodiments. FIG. 4 is an enlarged cross-sectional view illustrating portion ‘B’ in FIG. 2 in accordance with example embodiments. FIG. 5 is a plan view illustrating conductive bumps on a first semiconductor chip of FIG. 2 in accordance with example embodiments. FIG. 6 is an enlarged plan view illustrating portion ‘D’ in FIG. 5 in accordance with example embodiments. FIG. 7 is a perspective view of FIG. 6 in accordance with example embodiments. FIG. 2 includes a cross-sectional portion taken along the line C-C′ in FIG. 4 in accordance with example embodiments.

Referring to FIGS. 2 to 7, a semiconductor package 50 may include a buffer die 100 and first, second, third and fourth semiconductor chips 200a, 200b, 200c and 200d, respectively, as core dies that are sequentially stacked on the buffer die 100, first, second, third and fourth adhesive layers 300a, 300b, 300c and 300d, respectively, interposed between the buffer die 100 and the first, second, third and fourth semiconductor chips 200a, 200b, 200c and 200d, and a molding member 400 covering the first, second, third and fourth semiconductor chips 200a, 200b, 200c and 200d, respectively, on the buffer die 100. In one or more examples, the semiconductor package 50 may further include conductive bumps 52 provided on a lower surface of the buffer die 100.

In this embodiment, the first, second, third and fourth semiconductor chips 200a, 200b, 200c and 200d, respectively, may be substantially the same as or similar to each other. Thus, same or similar reference numerals may be used to refer to the same or like elements and any further repetitive explanation concerning the above elements may be omitted.

The buffer die 100 and the first, second, third and fourth semiconductor chips 200a, 200b, 200c and 200d, respectively, may be stacked on a package substrate such as a printed circuit board (PCB) or an interposer. In one or more embodiments, a semiconductor package as a multi-chip package is illustrated as including five stacked semiconductor chips 100, 200a, 200b, 200c and 200d, respectively. However, the semiconductor package may not be limited thereto, and for example, the semiconductor package may include 8, 12, 16 or 20 stacked semiconductor chips on the buffer die.

For example, the semiconductor package 50 may include a high bandwidth memory (HBM) device. The HBM package may include a processor chip and a broadband interface for faster data exchange. The HBM package may have an input/output (TSV I/O) structure including a large number of through silicon via structures to implement a wideband interface. Processor chips that require HBM package support may include a central processing unit (CPU), a graphics processing unit (GPU), a microprocessor, a microcontroller, an application processor (AP), or an application specific integrated circuit (ASIC) chip including a digital signal processing core and an interface for signal exchange.

The semiconductor package 50 may include the semiconductor chip 100 as a buffer die and the first, second, third and fourth semiconductor chips 200a, 200b, 200c and 200d, respectively, as memory dies, sequentially stacked. The first, second, third and fourth semiconductor chips 200a, 200b, 200d and 200d, respectively, may be electrically connected to each other by through electrodes such as through silicon vias (TSVs). The memory die may include a memory device, and the buffer die may include a controller controlling the memory device.

In example embodiments, the buffer die 100 may include a first substrate 110, a front insulating layer 120 provided on a first surface 112 of the first substrate 110, first bonding pads 130 provided on the front insulating layer 120, first through electrodes 140 penetrating the first substrate 110, a backside insulating layer 170 provided on a second surface 114 of the first substrate 110 opposite to the first surface 112, and second bonding pads 180 embedded within the backside insulating layer 170. In one or more examples, the dummy die 100 may further include conductive bumps 52 respectively provided on the first bonding pads 130. The buffer die 100 may be mounted on the interposer 30 of FIG. 1 via the conductive bumps 52. For example, the conductive bumps 52 may include solder bumps.

As illustrated in FIG. 2, the first substrate 110 may have the first surface 112 and the second surface 114 opposite to the first surface 112. The first surface may be an active surface, and the second surface may be an inactive surface. An active surface may be an interface that perpendicular to a direction of electron flow. An inactive surface may be an interface that defines a spatial boundary of a semiconductor device. Circuit patterns and cells may be formed on the first surface 112 of the first substrate 110. For example, the first substrate 110 may be a single crystal silicon substrate. The circuit patterns may include transistors, capacitors, diodes, etc. The circuit patterns may constitute circuit elements. Accordingly, the first semiconductor chip 100 may be a semiconductor device in which a plurality of the circuit elements are formed.

The front insulating layer 120 may be provided on the first surface 112 of the first substrate 110, that is, the active surface. The front insulating layer 120 may include a plurality of insulating layers 122, 124 and upper wirings 123 within the insulating layers. In one or more examples, the first bonding pads 130 may be provided in the outermost insulating layer of the front insulating layer 120.

The first through electrodes (through silicon vias, TSVs) 140 may be provided to vertically penetrate the first substrate 110 from the first surface 112 to the second surface 114 of the first substrate 110. A first end portion of the first through electrode 140 may contact the upper wiring of the front insulating layer. However, as understood by one of ordinary skill in the art, the embodiments are not limited to these configurations. For example, the first through electrode 140 may penetrate the front insulating layer and directly contact the first bonding pad 130.

The backside insulating layer 170 may be provided on the second surface 114 of the first substrate 110, for example, the backside surface. The second bonding pads 180 may be provided in the backside insulating layer 170. The second bonding pad 180 may be disposed on a surface of the first through electrode 140 exposed from the second surface 114 of the first substrate 110. Accordingly, the second bonding pad 180 may be electrically connected to the first through electrode 140.

In example embodiments, the first semiconductor chip 200a may include a substrate 210a, a front insulating layer 220a, first bonding pads 230a, a plurality of through electrodes 240a, a backside insulating layer 270a, and second bonding pads 280a. In one or more examples, the first semiconductor chip 200a may further include first conductive bumps CB1 respectively provided on the first bonding pads 230a.

The substrate 210a may have a first surface 212a and a second surface 214a opposite to the first surface 212a. The first surface may be an active surface, and the second surface may be an inactive surface. Circuit elements may be formed on the first surface 212a of the substrate 210a. The front insulating layer 220a as an insulation interlayer may be provided on the first surface 212a of the substrate 210a, for example, a front surface. The front insulating layer 220a may include a plurality of insulating layers 222a, 224a and upper wirings 223a within the insulating layers. In one or more examples, the first bonding pad 230a may be provided in the outermost insulating layer of the front insulating layer 220a. For example, the front insulating layer 220a may include a metal wiring layer 222a and a first passivation layer 224a sequentially stacked on the substrate 210a.

The through electrodes 240a may extend from the first surface 212a of the substrate 210a to the second surface 214a. The through electrode 240a may be electrically connected to the first bonding pad 230a through the upper wirings 223a. The backside insulating layer 270a may be provided on the second surface 214a of the second substrate 210a, e.g., a backside surface. The second bonding pad 280a may be provided in the backside insulating layer 270a. Accordingly, the first and second bonding pad 230a and 280a may be electrically connected to each other by the through electrode 240a.

As illustrated in FIG. 5, the first semiconductor chip 200a may have a square shape having four sides and four corner portions C1, C2, C3 and C4 between the sides adjacent to each other. The first semiconductor chip 200a may include a middle region MR, diagonal regions DR1, DR2, DR3 and DR4 extending from the middle region MR to the four corner portions C1, C2, C3 and C4 respectively, and peripheral regions PR1, PR2, PR3 and PR4 between the diagonal regions. A length of one side of the first semiconductor chip 200a may be within a range of about 8 mm to about 15 mm. A length in a diagonal direction of each diagonal region may be within a range of about 4 mm to about 6.5 mm. As illustrated in FIG. 5, a center of the middle region MR may coincide with a center of the semiconductor chip 200a. The middle region MR may be a square shape having a side with a length corresponding to a width of each of the diagonal regions. In one or more examples, the middle region MR may be a rectangular shape defined by a first length and a second length longer than the first length, where the first length defines a first width of two diagonal regions, and the second length defines a second width of two diagonal regions.

In example embodiments, the first semiconductor chip 200a may be stacked on the buffer die 100 via the first conductive bumps CB1. The first conductive bumps CB1 may include first bump structures 250a disposed on the first bonding pads 230a in the middle region MR respectively, and second bump structures 260a disposed on the first bonding pads 230a in the diagonal regions DR1, DR2, DR3 and DR4, respectively. Additionally, the first conductive bumps CB1 may include third bump structures 255a disposed on the first bonding pads 230a in the peripheral regions PR1, PR2, PR3 and PR4, respectively. When viewed in plan view, the first bump structures 250a and the third bump structures 255a may have a circular shape, and the second bump structures 260a may have an oval shape.

The first bump structure 250a may include a first pillar bump 252a, which has a circular shape, and a first solder bump 254a, which is formed on the first pillar pump 252a. The second bump structure 260a may include a second pillar bump 262a, which has an elliptical shape, and a second solder bump 264a, which is formed on the second pillar bump 262a. The third bump structure 255a may include a third pillar bump 256a, which has a circular shape, and a third solder bump 258a, which is formed on the third pillar bump.

For example, the first, second and third pillar pumps may have a single layer structure. The first, second and third pillar pumps may include a plating pattern layer including copper (Cu). The first, second and third solder bumps may include solder. The first, second and third solder bumps may include, for example, tin (Sn), tin/silver (Sn/Ag), tin/copper (Sn/Cu), tin/indium (Sn/In), tin/silver/copper (Sn/Ag/Cu), etc.

In one or more examples, the first, second, and third pillar pumps may have a multilayer structure. In one or more examples, the first, second and third pillar pumps may include sequentially stacked first, second and third plating pattern layers. For example, the first and third plating pattern layers may include copper (Cu), and the second plating pattern layer may include nickel (Ni).

In example embodiments, a first adhesive layer 300a may be provided to fill a space between the first conductive bumps CB1 between the buffer die 100 and the first semiconductor chip 200a. For example, the first adhesive layer may include a non-conductive film (NCF).

For example, the first semiconductor chip 200a and the buffer die 100 may be attached to each other by a thermal compression process using the non-conductive film. In one or more examples, the thermal compression process may use heat and force to attach the first semiconductor chip 200a to the buffer die 100. In the thermal compression process, the non-conductive film may be liquefied and have fluidity, may flow between the first semiconductor chip 200a and the buffer die 100 and between the first conductive bumps CB1, and then may be cured to fill the space between the first conductive bumps CB1. A portion of the cured first adhesive layer 300a may protrude from a side surface of the first semiconductor chip 200a.

In example embodiments, the second semiconductor chip 200b may include a substrate 210b, a front insulating 220b, first bonding 230b, a plurality of through electrodes 240b, a backside insulating layer 270b, and second bonding pads 280b. In one or more examples, the second semiconductor chip 200b may further include second conductive bumps CB2 respectively provided on the first bonding pads 230b.

As illustrated in FIG. 4, the front insulating layer 220b as an insulation interlayer may be provided on a first surface 212b of the substrate 210b, for example, a front surface. The front insulating layer 220b may include a plurality of insulating layers 222b, 224b and upper wirings 223b within the insulating layers. In one or more examples, the first bonding pad 230b may be provided in the outermost insulating layer of the front insulating layer 220b. For example, the front insulating layer 220b may include a metal wiring layer 222b and a first passivation layer 224b sequentially stacked on the substrate 210b.

The through electrodes 240b may extend from the first surface 212b of the substrate 210a to a second surface 214b. The through electrode 240b may be electrically connected to the first bonding pad 230b through the upper wirings 223b. The backside insulating layer 270b may be provided on the second surface 214b of the substrate 210b, that is, a backside surface. The second bonding pad 280b may be provided in the backside insulating layer 270b. Accordingly, the first and second bonding pad 230b and 280b may be electrically connected to each other by the through electrode 240b.

In example embodiments, the second semiconductor chip 200b may be stacked on the first semiconductor chip 200a via the second conductive bumps CB2. The second conductive bumps CB2 may include first bump structures 250b disposed on the first bonding pads 230b in the middle region MR respectively, and second bump structures 260b disposed on the first bonding pads 230b in the diagonal regions DR1, DR2, DR3 and DR4, respectively. Although FIG. 4 only illustrates DR1, as understood by one of ordinary skill in the art, the structure illustrated in FIG. 4 may be similarly applied to DR2, DR3, and DR4. In one or more examples, the second conductive bumps CB2 may include third bump structures disposed on the first bonding pads 230b in the peripheral regions PR1, PR2, PR3 and PR4, respectively. When viewed in plan view, the first bump structures 250b and the third bump structures may have a circular shape, and the second bump structures 260b may have an oval shape.

In one or more examples, a second adhesive layer 300b may be provided to fill a space between the second conductive bumps CB2 between the first semiconductor chip 200a and the second semiconductor chip 200b. For example, the second adhesive layer may include a non-conductive film (NCF). The second semiconductor chip 200b and the first semiconductor chip 200a may be attached to each other by a thermal compression process using the non-conductive film. In the thermal compression process, the non-conductive film may be liquefied and have fluidity, may flow between the second semiconductor chip 200b and the first semiconductor chip 200a and between the second conductive bumps CB2, and then may be cured to fill the space between the second conductive bumps CB2. A portion of the cured second adhesive layer 300b may protrude from a side surface of the second semiconductor chip 200b.

In example embodiments, the third semiconductor chip 200c may be stacked on the second semiconductor chip 200b via third conductive bumps CB3. The third conductive bumps CB3 may include first bump structures 250c disposed on first bonding pads 230c in the middle region MR respectively, and second bump structures 260c disposed on the first bonding pads 230c in the diagonal regions DR1, DR2, DR3 and DR4, respectively. Additionally, the third conductive bumps CB3 may include third bump structures disposed on the first bonding pads 230c in the peripheral regions PR1, PR2, PR3 and PR4, respectively. When viewed in plan view, the first bump structures 250c and the third bump structures may have a circular shape, and the second bump structures 260c may have an oval shape.

In one or more examples, a third adhesive layer 300c (FIG. 2) may be provided to fill a space between the third conductive bumps CB3 between the second semiconductor chip 200b and the third semiconductor chip 200c. For example, the third adhesive layer 300c may include a non-conductive film (NCF). The third semiconductor chip 200c and the second semiconductor chip 200b may be attached to each other by a thermal compression process using the non-conductive film.

In example embodiments, the fourth semiconductor chip 200d may be stacked on the third semiconductor chip 200c via fourth conductive bumps CB4. The fourth conductive bumps CB4 may include first bump structures 250d disposed on first bonding pads 230d in the middle region MR respectively, and second bump structures 260d disposed on the first bonding pads 230d in the diagonal regions DR1, DR2, DR3 and DR4, respectively. In one or more examples, the fourth conductive bumps CB4 may include third bump structures disposed on the first bonding pads 230d in the peripheral regions PR1, PR2, PR3 and PR4, respectively. When viewed in plan view, the first bump structures 250d and the third bump structures may have a circular shape, and the second bump structures 260d may have an oval shape.

In one or more examples, a fourth adhesive layer 300d may be provided to fill a space between the fourth conductive bumps CB4 between the third semiconductor chip 200c and the fourth semiconductor chip 200d. For example, the fourth adhesive layer may include a non-conductive film (NCF). The fourth semiconductor chip 200d and the third semiconductor chip 200d may be attached to each other by a thermal compression process using the non-conductive film.

As illustrated in FIGS. 5 to 7, the first bump structures 250a having a circular shape may be disposed on the middle region MR of the first semiconductor chip 200a, and the second bump structures 260a having an oval shape may be disposed on the diagonal regions DR1, DR2, DR3, and DR4 that extending from the middle region MR to the corner regions C1, C2, C3 and C4, respectively. The second bump structure 260a may be arranged such that the long axis (Xa) of the ellipse faces the middle region MR. A ratio (L/D) of the long axis to the short axis of the second bump structure 260a may be at least 1.5. The second bump structure 260a may have a major axis length (L) within a range of 15 μm to 40 μm and a minor axis length (D) within a range of 8 μm to 20 μm. The first bump structure 250a may have a diameter within a range of 10 μm to 20 μm. In one or more examples, the major axis length is longer than the minor axis length.

In the thermal compression process of bonding the first semiconductor chip 200a onto the buffer die 100, when the non-conductive film having fluidity flows through the second bump structures 260a along a diagonal direction in the diagonal regions DR1, DR2, DR3, and DR4 that have relatively long lengths, since the flow resistance coefficient CD of the second bump structure 260a is relatively low compared to the first and third bump structures, a flow rate of the non-conductive film flowing through the diagonal region may be increased. Accordingly, the time for the non-conductive film to reach from the middle region MR to the corner portions C1, C2, C3, and C4 may be advantageously reduced, to thereby prevent the non-conductive film from being unfilled in the corner portions.

As mentioned above, the semiconductor package 50 may include the first, second, third and fourth semiconductor chips 200a, 200b, 200c, and 200d sequentially stacked on the buffer die 100 via the first, second, third and fourth conductive bumps CB1, CB2, CB3 and CB4, and the first, second, third and fourth adhesive layers 300a, 300b, 300c, and 300d filling spaces between the first to fourth conductive bumps between the first to fourth semiconductor chips and adhering the first to fourth semiconductor chips to each other. The first, second, third, and fourth conductive bumps may include the first bump structures 250a, 250b, 250c, 250d disposed in the middle regions MR of the first to fourth semiconductor chips respectively, and having a circular shape, and the second bump structures 260a, 260b, 260c, 260d disposed in the diagonal regions respectively and having an oval shape.

The second bump structure may be arranged such that the long axis Xa of the oval shape extends towards the middle region MR. A ratio (L/D) of the long axis to the short axis of the second bump structure may be at least 1.5. In the bonding processes of the first to fourth semiconductor chips, the flow resistance coefficient (CD) of the second bump structure with respect to the non-conductive film having fluidity may be relatively reduced compared to the first bump structure due to the oval shape.

Accordingly, in the bonding process, when the non-conductive film passes through the second bump structures along the diagonal direction in the diagonal regions DR1, DR2, DR3, and DR4, the flow rate of the non-conductive film may be advantageously increased. Thus, the time for the non-conductive film to reach from the middle region MR to the corner portions C1, C2, C3, and C4 may be reduced, thereby preventing the non-conductive film from being unfilled in the corner portions.

Hereinafter, a method of manufacturing the semiconductor package of FIG. 1 will be described.

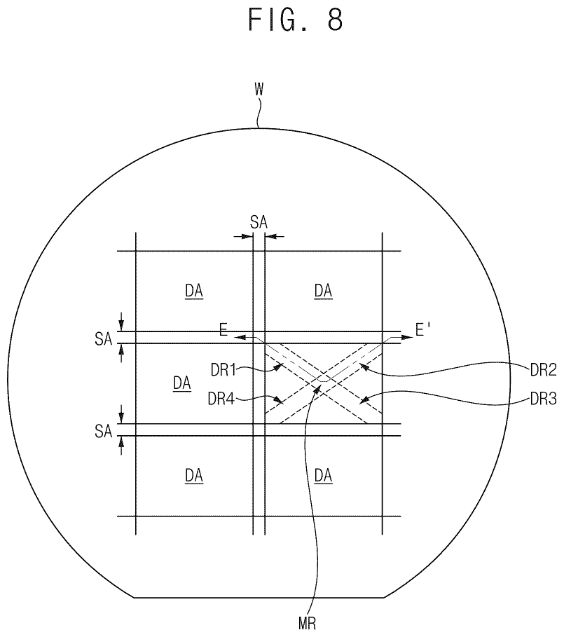

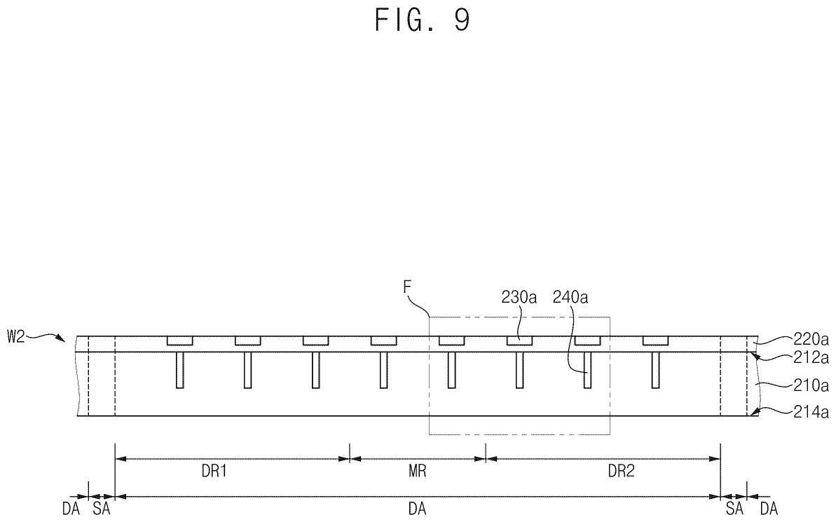

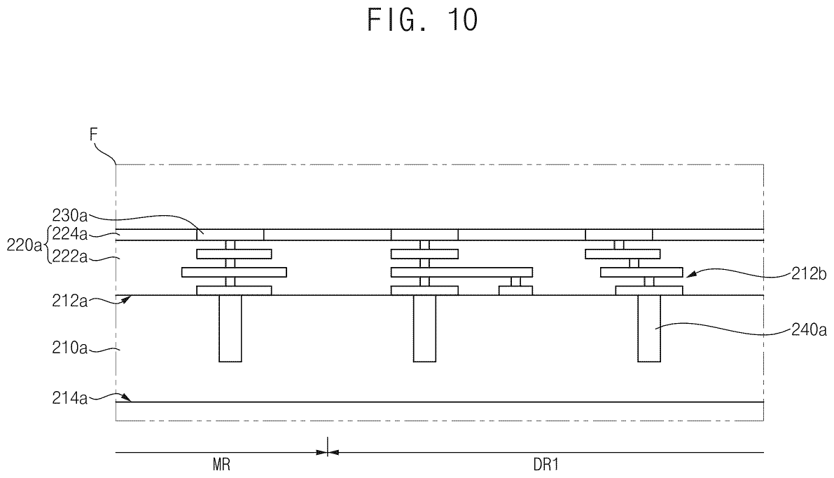

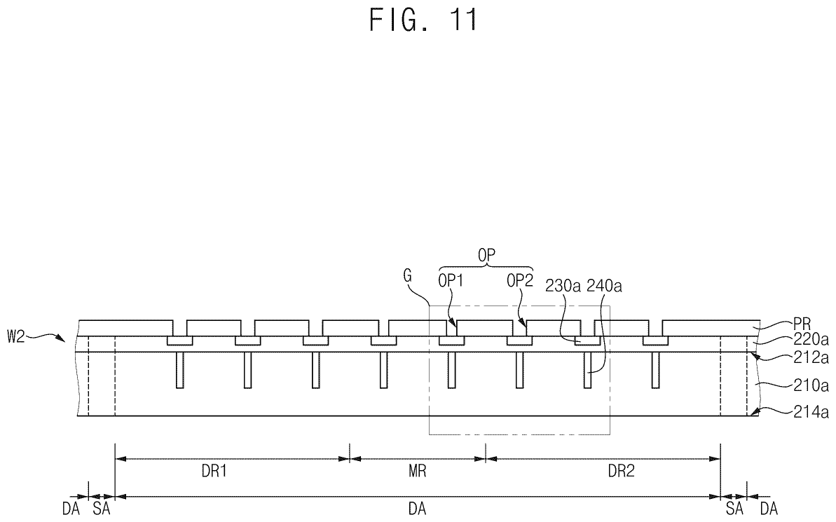

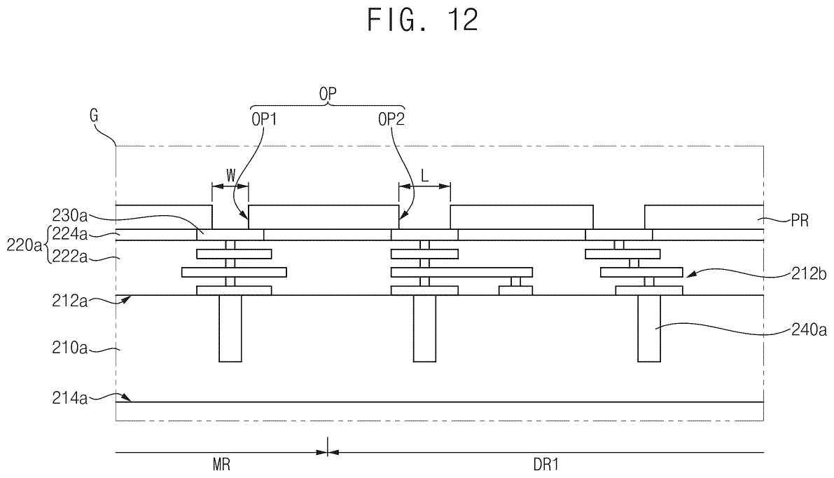

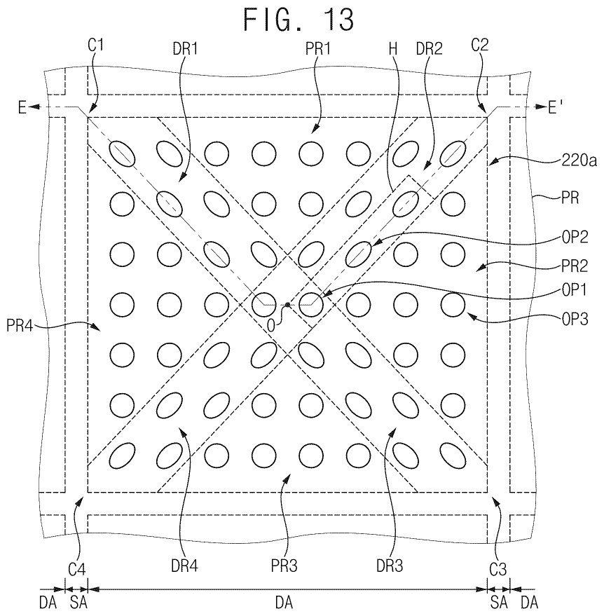

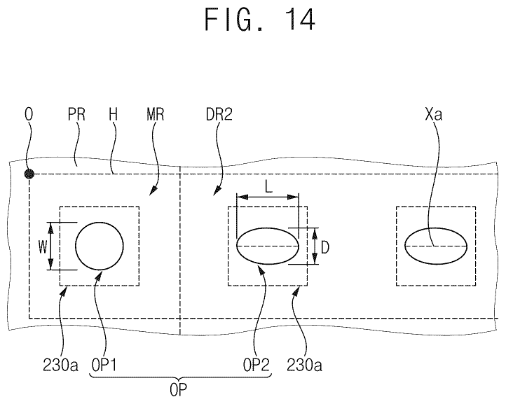

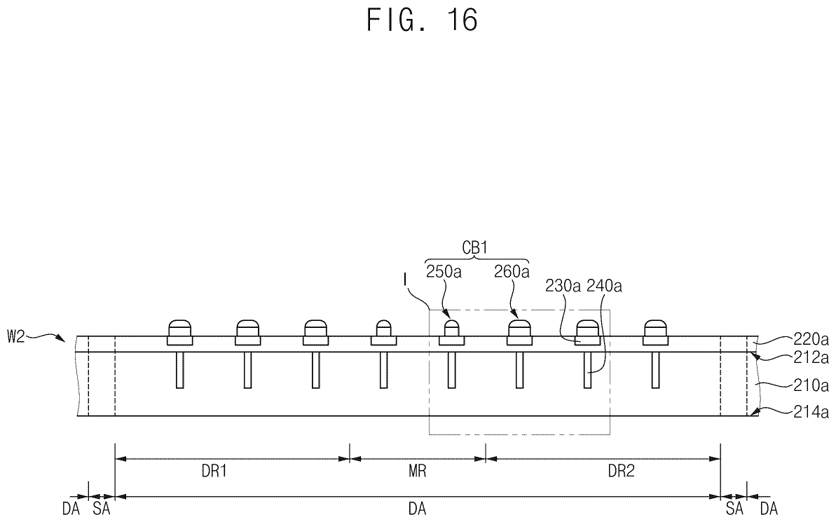

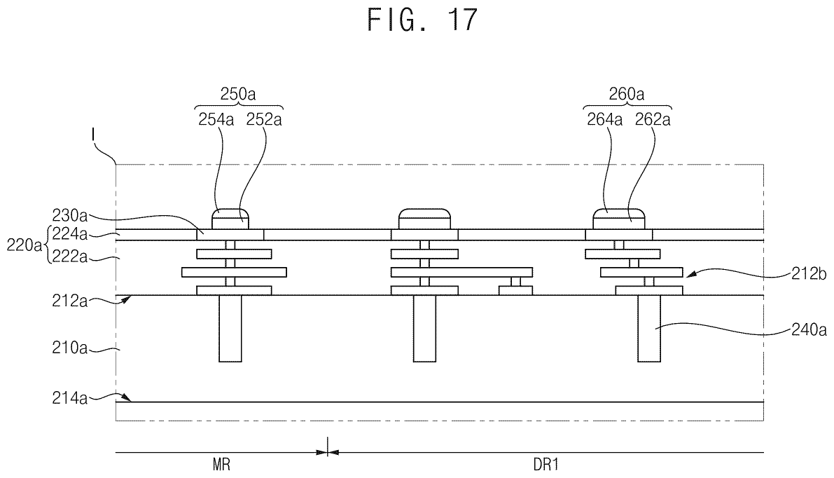

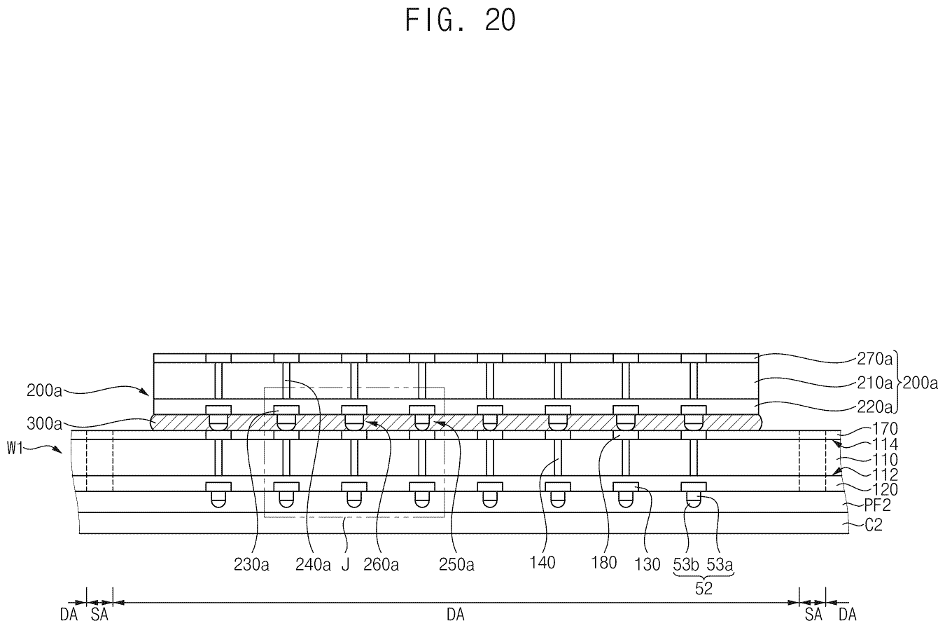

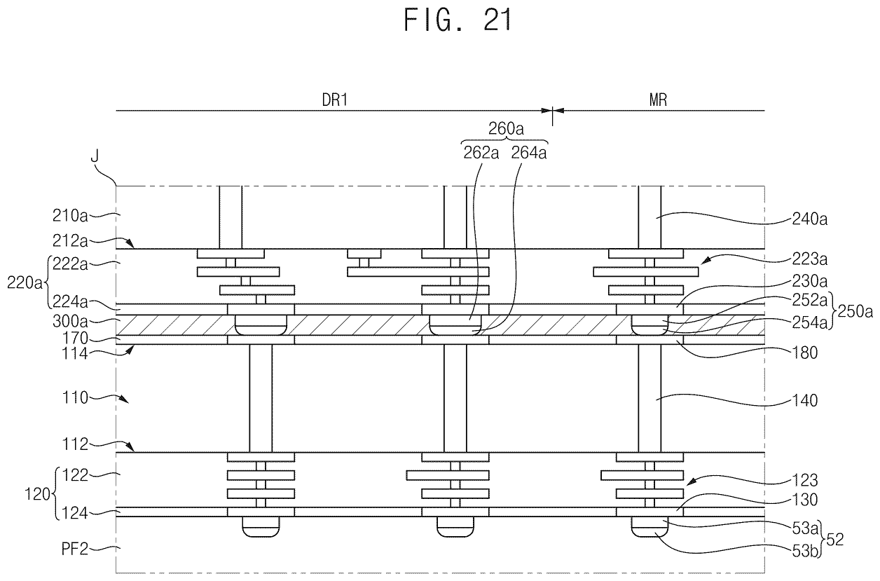

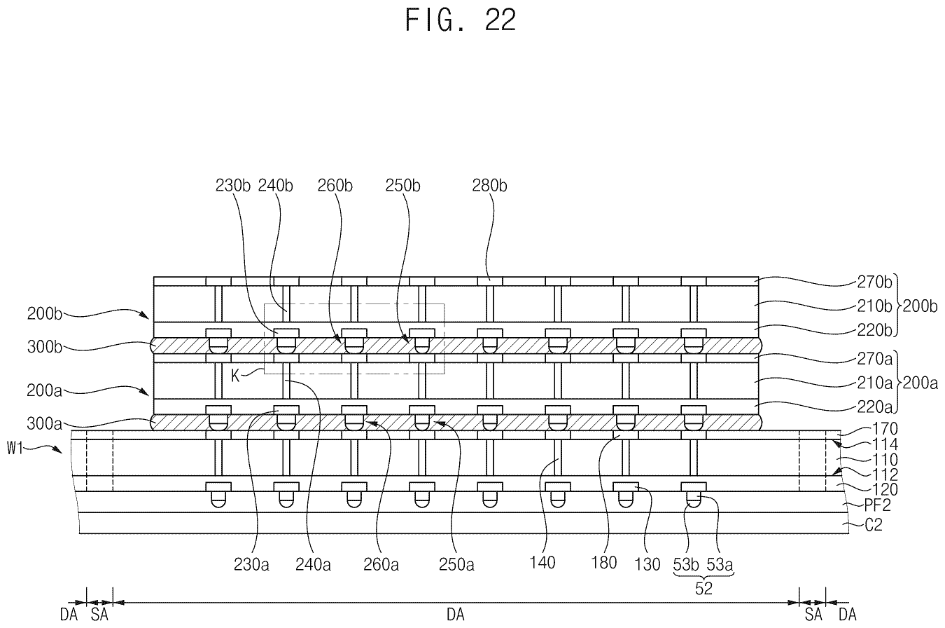

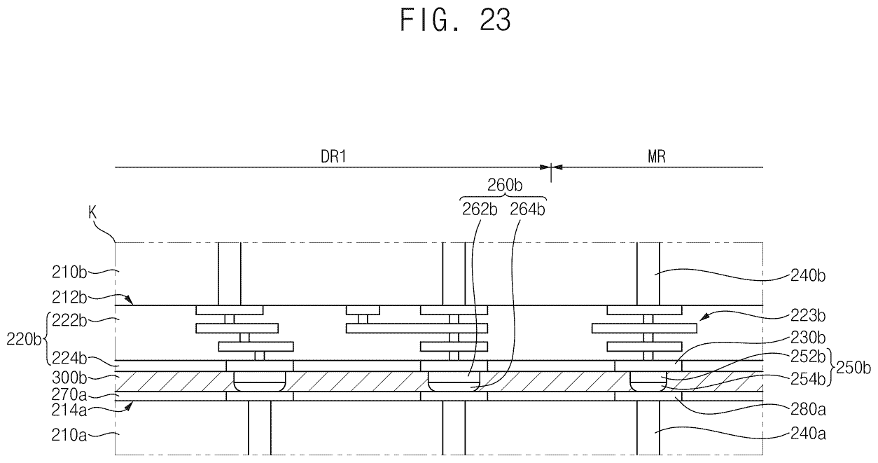

FIGS. 8 to 25 are views illustrating a method of manufacturing a semiconductor package in accordance with example embodiments. FIG. 8 is a plan view illustrating a semiconductor wafer in which first semiconductor chips are formed in accordance with example embodiments. FIGS. 12 and 14 are enlarged cross-sectional views illustrating portion ‘G’ in FIG. 11 in accordance with example embodiments. FIG. 13 is a plan view illustrating a photoresist pattern formed on the semiconductor wafer of FIG. 12 in accordance with example embodiments. FIG. 14 is an enlarged cross-sectional view illustrating portion ‘H’ in FIG. 13 in accordance with example embodiments. FIG. 17 is an enlarged cross-sectional view illustrating portion ‘I’ in FIG. 16 in accordance with example embodiments. FIG. 21 is an enlarged cross-sectional view illustrating portion ‘J’ in FIG. 20 in accordance with example embodiments. FIG. 23 is an enlarged cross-sectional view illustrating portion ‘K’ in FIG. 22 Q301010.

Referring to FIGS. 8 to 10, a second wafer W2 in which a plurality of first semiconductor chips (core dies) are formed may be provided.

In example embodiments, the second wafer W2 may include a substrate 210a having a first surface 212a and a second surface 214a opposite to the first surface 212a. The second wafer W2 may include a die region DA and a scribe lane region SA surrounding the die region DA. The second wafer W2 may be cut along the scribe lane region SA that divides a plurality of the die regions DA of the second wafer W2 by a following sawing process to be individualized into a plurality of first semiconductor chips.

The die region DA may have a square shape having four sides and four corner portions between the sides adjacent to each other. The die region DA may include a middle region MR and diagonal regions DR1, DR2, DR3, and DR4 extending from the middle region MR to the four corner portions, respectively.

Circuit elements may be formed in the die region DA on the first surface 212a of the substrate 210a. The circuit element may include a plurality of memory devices. Examples of the memory device may include a volatile semiconductor memory device and a non-volatile semiconductor memory device. Examples of the volatile semiconductor memory device may be DRAM, SRAM, etc. Examples of the non-volatile semiconductor memory device may be EPROM, EEPROM, Flash EEPROM, etc. However, the memory device may be any memory structure known to one of ordinary skill in the art.

For example, the substrate 210a may include silicon, germanium, silicon-germanium, or III-V compounds, e.g., GaP, GaAs, GaSb, etc. In some embodiments, the substrate 210a may be a silicon-on-insulator (SOI) substrate, or a germanium-on-insulator (GOI) substrate.

The circuit elements may include, for example, transistors, capacitors, wiring structures, etc. The circuit elements may be formed on the first surface 212 of the substrate 210a by performing a fab process called a front-end-of-line (FEOL) process for manufacturing semiconductor devices. A surface of the second substrate on which the FEOL process is performed may be referred to as a front surface of the substrate, and a surface opposite to the front surface may be referred to as a backside surface. The FEOL process may be the first stage of integrated circuit fabrication, where individual components may be patterned into a semiconductor substrate. The FEOL process may be used to build transistor and other components (e.g., capacitors and resistors) directly inside the wafer. An insulation interlayer may be formed on the first surface 212a of the substrate 210a to cover the circuit elements.

In example embodiments, the second wafer W2 may include a front insulating layer 220a provided on the first surface 212a of the substrate 210a. The front insulating layer 220a may include a metal wiring layer 222a and a first passivation layer 224a sequentially stacked on the substrate 210a. The front insulating layer may be formed by performing a wiring process called a back-end-of-line (BEOL) process. The BEOL process may include depositing metal wiring between individual devices on a wafer and may be performed after the FEOL process. The BEOL process may involve electrically connecting transistors and components. A first bonding pad 230a may be provided in the outermost insulating layer of the front insulating layer 220a.

The metal wiring layer 222a may include a plurality of insulating layers, upper wirings 223a within the plurality of insulating layers, and the fist bonding pad 230a may be formed on uppermost wirings of the plurality of upper wirings 223a. For example, the upper wirings may include aluminum (Al), copper (Cu), tin (Sn), nickel (Ni), gold (Au), platinum (Pt), or an alloy thereof. The first passivation layer 224a may be formed on the metal wiring layer 222a and may cover at least a portion of the first bonding pad 230a. For example, the insulating layers may be formed to include an oxide such as silicon oxide, carbon-doped oxide, or fluorine-doped oxide. The first passivation layer may include a first protective layer including an oxide layer and a second protective layer including a nitride layer, which are sequentially stacked. The first protective layer may include silicon oxide, and the second protective layer may include silicon nitride or silicon carbonitride.

The first bonding pad 230a may be provided in the first passivation layer 224a. The first bonding pad 230a may be exposed through the outer surface of the first passivation layer 224a. In one or more examples, an insulating interlayer may be provided on the first surface 212a of the substrate 210a to cover the circuit patterns. The insulating interlayer may be formed to include, for example, silicon oxide or a low dielectric material. The insulating interlayer may include lower wirings that are electrically connected to the circuit patterns therein. Accordingly, the circuit pattern may be electrically connected to the first bonding pad 230a through the lower wirings and the upper wirings.

In example embodiments, the second wafer W2 may include through electrodes 240a that at least partially penetrate the substrate 210. The through electrodes 240a may extend from the first surface 212a of the substrate 210a to a predetermined depth. The through electrode 240a may contact the lowermost wiring of the upper wirings. Accordingly, the through electrode 240a may be electrically connected to the first bonding pad 230a through the upper wirings 223a.

Referring to FIGS. 11 to 18, first conductive bumps CB1 as conductive connection members may be formed on the first bonding pads 230a on the first surface 212a of the substrate 210a, respectively.

First, as illustrated in FIGS. 11 to 14, a seed layer may be formed on the first bonding pads 230a of the substrate 210a, and a photoresist pattern PR having openings OP that expose conductive bump regions may be formed on the seed layer. The seed layer may be a thin layer of metal deposited on the first bonding pads 230a to improve the properties the following components deposited thereon.

The seed layer may include titanium/copper (Ti/Cu), nickel/gold (Ni/Au), titanium/palladium (Ti/Pd), titanium/nickel (Ti/Ni), chrome/copper (Cr/Cu) or an alloy thereof. The seed layer may be formed by a sputtering process.

After a photoresist layer is formed on the seed layer on the first surface 212a of the substrate 210a, an exposure process may be performed on the photoresist layer to form the photoresist pattern PR having the openings OP. The openings OP of the photoresist pattern PR may include first openings OP1 that expose first bump structure regions in the middle region MR and second openings OP2 that expose second bump structure regions in the diagonal regions DR1, DR2, DR3, and DR4. The openings OP of the photoresist pattern PR may include third openings OP3 that expose third bump structure regions in peripheral regions PR1, PR2, PR3, and PR4 between the diagonal regions.

When viewed in plan view, each of the first openings OP1 may have a circular shape and each of the second openings OP2 may have an elliptical shape having a long axis (major axis) and a short axis (minor axis). The third openings OP3 may have a shape the same as the first opening OP1. The second opening OP2 may have an oval shape. The second openings OP2 may be formed such that the long axes Xa of the second openings OP2 face the middle region MR. The first opening OP1 may have a diameter W within a range of 10 μm to 20 μm. The major axis of the second opening OP2 may have a length L within a range of 15 μm to 40 μm, and the minor axis of the second opening OP2 may a length D within a range of 8 μm to 20 μm.

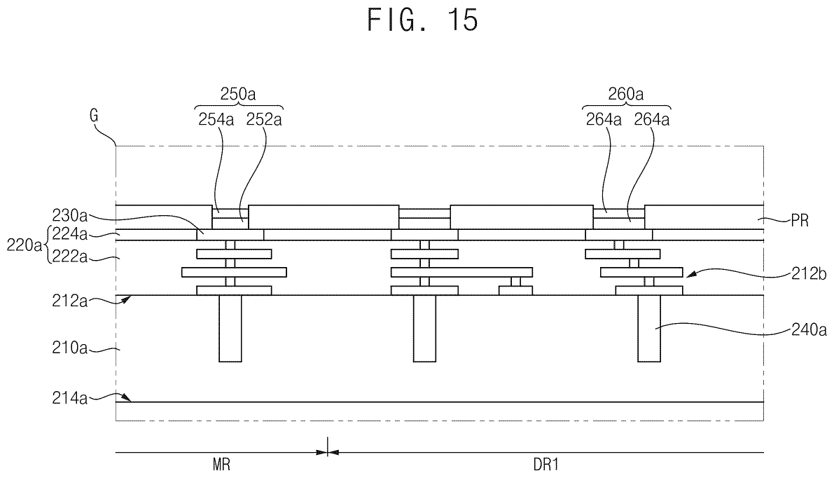

As illustrated in FIG. 15, the first, second and third openings OP1, OP2 and OP3 of the photoresist pattern PR may be filled up with a conductive material to form the first conductive bumps.

The first conductive bumps may be formed by performing a plating process on the seed layer. For example, a first bump structure 250a having a circular shape may be formed in the first opening OP1 that is formed in the middle region MR, second bump structures 260a having elliptic shapes may be formed in the second openings OP2 that are formed in the diagonal regions DR1, DR2, DR3 and DR4, and third bump structure having circular shapes may be formed in the third openings OP3 that are formed in the peripheral regions PR1, PR2, PR3 and PR4.

The first bump structure 250a may include a first pillar bump 252a, which has a circular shape, and a first solder bump 254a, which is formed on the first pillar pump 252a. The second bump structure 260a may include a second pillar bump 262a, which has an elliptical shape, and a second solder bump 264a, which is formed on the second pillar bump 262a. The third bump structure may include a third pillar bump, which has a circular shape, and a third solder bump, which is formed on the third pillar bump.

For example, the first, second and third pillar pumps may have a single layer structure. The first, second and third pillar pumps may include a plating pattern layer including copper (Cu). The first, second and third solder bumps may include solder. The first, second and third solder bumps may include, for example, tin (Sn), tin/silver (Sn/Ag), tin/copper (Sn/Cu), tin/indium (Sn/In), tin/silver/copper (Sn/Ag/Cu), etc.

In one or more examples, the first, second and third pillar pumps may have a multilayer structure. In one or more examples, the first, second and third pillar pumps may include sequentially stacked first, second and third plating pattern layers. For example, the first and third plating pattern layers may include copper (Cu), and the second plating pattern layer may include nickel (Ni).

Then, the photoresist pattern PR may be removed from the wafer W2 and portions of the seed layer exposed by the bump structures may be removed to form a seed layer pattern.

The first conductive bumps CB1 may include the first bump structures 250a disposed on the first bonding pads 230a in the middle region MR respectively, and the second bump structures 260a disposed on the first bonding pads 230a in the diagonal regions DR1, DR2, DR3 and DR4, respectively. In one or more examples, the first conductive bumps may include the third bump structures disposed on the first bonding pads 230a in the peripheral regions PR1, PR2, PR3 and PR4, respectively. The first bump structure 250a may have a first thickness H1, and the second bump structure 260a may have a second thickness H2 that is greater than or equal to the first thickness H1. The third bump structure may have the first thickness H1. The first and second thicknesses H1 and H2 may be within a range of 10 μm to 50 μm.

When the thicknesses of the first and second pillar bumps 252a and 262 are relatively small, the first and second pillar bumps 252a and 262a may be referred to as first bonding pads and the first bonding pads 230a may be referred to as first redistribution pads.

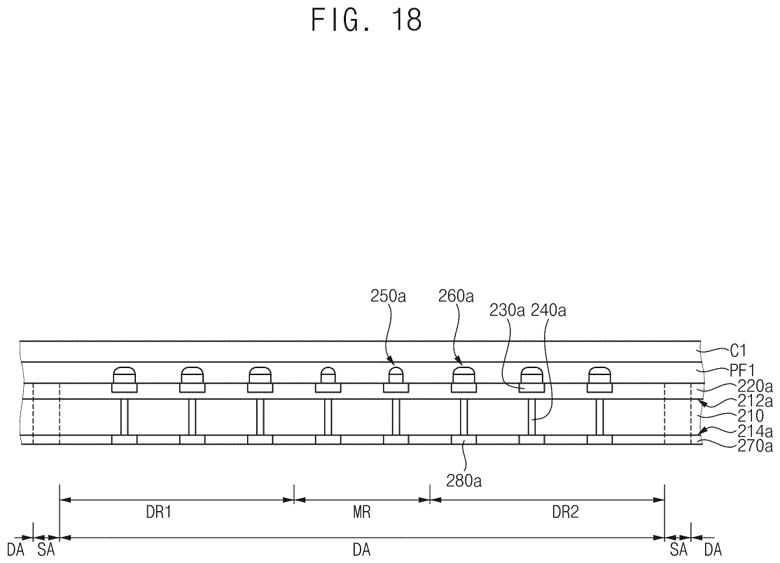

Referring to FIG. 18, a backside insulating layer 270a with a second bonding pad 280a may be formed on the second surface 214a of the substrate 210a.

First, the structure of FIG. 16 may be turned over, the second wafer W2 may be attached to a first carrier substrate C1 using a first adhesive film PF1, and then, the second surface 214a of the substrate 210a may be removed until portions of the through electrodes 240a are exposed.

The second surface 214a of the substrate 210a may be partially removed by a grinding process, such as a chemical mechanical polishing (CMP) process. Accordingly, a thickness of the substrate 210a may be reduced to a desired thickness. For example, the substrate 210a may have the thickness within a range of about 30 μm to 150 μm. Then, a silicon recess etching process may be performed on the second surface 214a of the substrate 210a to expose one end portion of the through electrode 240a from the second surface 214a of the substrate 210a.

The backside insulating layer 270a as a second passivation layer having the second bonding pad 280a that is electrically connected to the through electrode 240a may be formed on the second surface 214a of the substrate 210a. For example, after forming the backside insulating layer 270a on the second surface 214a of the substrate 210a, an opening may be formed in the backside insulating layer 270a to expose the through electrode 240a, and a plating process may be performed to form the second bonding pad 280a in the opening. The second bonding pad 280a may be disposed on the exposed surface of the through electrode 240a. The backside insulating layer 270a may include silicon oxide, carbon-doped silicon oxide, silicon carbonitride (SiCN), etc. Accordingly, the first and second bonding pads 230a and 280a may be electrically connected to each other by the through electrode 240a.

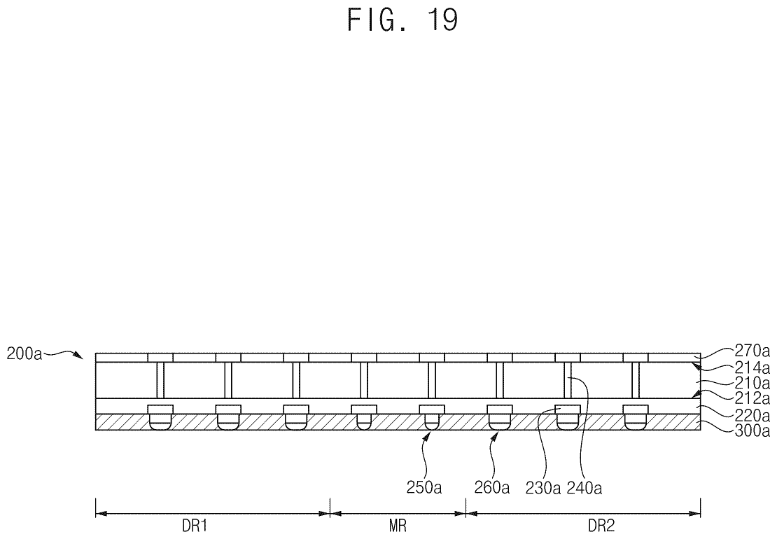

Referring to FIG. 19, a first adhesive layer 300a may be formed on the front insulating layer 220a on the first surface 212a of the substrate 210a, and the second wafer W2 may be cut along the scribe lane region SA to form an individualized first semiconductor chip 200a. The second wafer W2 may be cut by a sawing process.

The first adhesive layer 300a may be formed to cover the first conductive bumps. For example, the first adhesive layer 300a may include a thermosetting resin. The first adhesive layer 300a may include a non-conductive film (NCF).

Referring to FIGS. 20 and 21, the first semiconductor chip 200a may be stacked on a first wafer W1. The first semiconductor chip 200a may be stacked on the first wafer W1 via the first conductive bumps. The first semiconductor chip 200a may be attached to the first wafer W1 by the first adhesive layer 300a.

In example embodiments, first, conductive bumps 52 may be formed on a front surface of the first wafer W1 in which a plurality of buffer dies are formed, and a second adhesive film PF2 may formed on the front surface of the first wafer W1 to cover the conductive bumps 52. Then, the first wafer W1 may be attached onto a second carrier substrate C2 using the second adhesive film PF2.

The first wafer W1 may include a first substrate 110 having a first surface 112 and a second surface 114 opposite to the first surface 112. The first wafer W1 may include a die region DA and a scribe lane region SA surrounding the die region DA. The first wafer W1 may be cut along the scribe lane region SA that divides a plurality of the die regions DA of the first wafer W1 by a following sawing process to be individualized into a plurality of buffer dies.

Then, the first semiconductor chip 200a may be stacked on the first wafer W1 by using a substrate support system WSS. The first semiconductor chips 200a may be disposed on the first wafer W1 to correspond to the die regions DA, respectively. The first semiconductor chip 200a may be arranged such that the first surface 212a of the substrate 210a of the first semiconductor chip 200a faces the first wafer W1.

The first semiconductor chip 200a may be attached on the first wafer W1 by performing a thermal compression process at a predetermined temperature (e.g., about 400° C. or less). Through the thermal compression process, the first semiconductor chip 200a and the first wafer W1 may be bonded to each other. In one or more examples, the predetermined temperature may be applied for a period of time sufficient to attach the first semiconductor chip 200a to the first wafer W1 and to liquefy the non-conductive film.

The first conductive bumps of the first semiconductor chip 200a may be bonded to second bonding pads 180 of the buffer die through the thermal compression process. The first bonding pad 230a of the first semiconductor chip 200a may be electrically connected to the second bonding pad 180 of the buffer die through the first conductive bump.

In the thermal compression process, the non-conductive film may be liquefied and may have fluidity, and may flow between the first semiconductor chip 200a and the first wafer W1. The non-conductive film having fluidity may flow between the first conductive bumps, and then may be cured to fill a space between the first conductive bumps. A portion of the cured first adhesive layer 300a may protrude from a side surface of the first semiconductor chip 200a.

The first bump structures 250a having a circular shape may be disposed in the middle region MR of the first semiconductor chip 200a, and the second bump structures 260a having an oval shape may be disposed in the diagonal regions DR1, DR2, DR3, and DR4 that extend from the middle region MR of the first semiconductor chip 200a to the four corner portions C1, C2, C3, and C4, respectively. The third bump structures having a circular shape may be disposed in the peripheral regions of the first semiconductor chip 200a. The second bump structure 260a may be arranged such that the long axis Xa of the oval shape extends towards the middle region MR. A ratio (L/D) of the long axis to the short axis of the second bump structure 260a may be at least 1.5.

When the non-conductive film having fluidity flows through the second bump structures 260a along a diagonal direction in the diagonal regions DR1, DR2, DR3, and DR4 that have relatively long lengths, since the flow resistance coefficient CD of the second bump structure 260a is relatively low compared to the first bump structure, a flow rate of the non-conductive film flowing through the diagonal region may be relatively increased. Accordingly, the time for the non-conductive film to reach from the middle region MR to the corner portions C1, C2, C3, and C4 may be reduced, thereby preventing the non-conductive film from being unfilled in the corner portions.

Referring to FIGS. 22 and 23, a second semiconductor chip 200b may be stacked on the first semiconductor chip 200a.

First, processes the same as or similar to the processes described with reference to FIGS. 8 to 19 may be performed to form an individualized second semiconductor chip 200b, and processes the same as or similar to the processes described with reference to FIGS. 20 and 21 may be performed to stack the second semiconductor chip 200b on the first semiconductor chip 200a.

In example embodiments, the second semiconductor chip 200b may be stacked on the first semiconductor chip 200a via second conductive bumps. A second adhesive layer 300b may be adhered on the second semiconductor chip 200b to adhere the second semiconductor chip 200b onto the first semiconductor chip 200a. The second adhesive layer 300b may be adhered on a second front insulation layer 220b to cover the second conductive bumps. The second semiconductor chip 200b may be attached onto the first semiconductor chip 200a using the second adhesive layer 300b. The second semiconductor chip 200b may be arranged such that a first surface 212b of a substrate 210b of the second semiconductor chip 200b faces the first semiconductor chip 200a. The second adhesive layer 300b may include a non-conductive film (NCF).

The second semiconductor chip 200b may be attached on the first semiconductor chip 200a by performing a thermal compression process. The second conductive bumps of the second semiconductor chip 200b may be bonded to the second bonding pads 280a of the first semiconductor chip 200a through the thermal compression process. A first bonding pad 230b of the second semiconductor chip 200b may be electrically connected to the second bonding pad 280a of the first semiconductor chip 200a through the second conductive bump.

In the thermal compression process, the non-conductive film may be liquefied and may have fluidity, and may flow between the second semiconductor chip 200b and the first semiconductor chip 200a. The non-conductive film having fluidity may flow between the second conductive bumps and then may be cured to fill a space between the second conductive bumps. A portion of the cured second adhesive layer 300b may protrude from a side surface of the second semiconductor chip 200b.

First bump structures 250b having a circular shape may be disposed in a middle region MR of the second semiconductor chip 200b, and second bump structures 260b having an oval shape may be disposed in diagonal regions DR1, DR2, DR3, and DR4 that extend from the middle region MR of the second semiconductor chip 200b to four corner portions, respectively. Third bump structures having a circular shape may be disposed in peripheral regions of the second semiconductor chip 200b. The second bump structure 260b may be arranged such that the long axis Xa of the oval shape extends towards the middle region MR. A ratio (L/D) of the long axis to the short axis of the second bump structure 260b may be at least 1.5.

When the non-conductive film having fluidity flows through the second bump structures 260b along a diagonal direction in the diagonal regions DR1, DR2, DR3, and DR4 that have relatively long lengths, since the flow resistance coefficient CD of the second bump structure 260b is relatively low compared to the first bump structure, a flow rate of the non-conductive film flowing through the diagonal region may be relatively increased. Accordingly, the time for the non-conductive film to reach from the middle region MR to the corner portions may be reduced, to thereby prevent the non-conductive film from being unfilled in the corner portions.

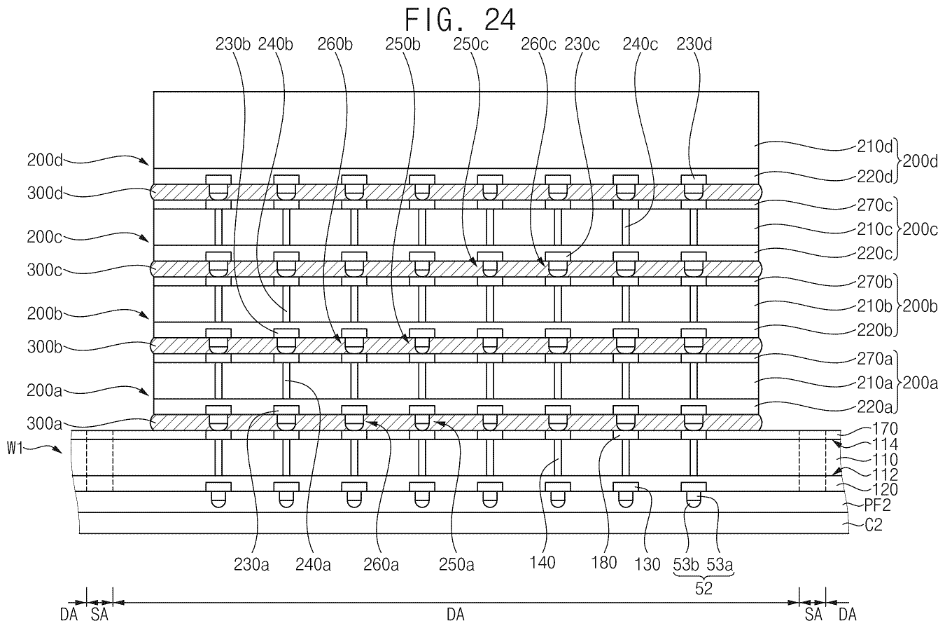

Referring to FIG. 24, processes the same as or similar to the processes described with reference to FIGS. 22 and 23 may be performed to stack a third semiconductor chip 200c on the second semiconductor chip 200b and stack a fourth semiconductor chip 200d on the third semiconductor chip 200c.

In example embodiments, the third semiconductor chip 200c may be attached onto the second semiconductor chip 200b using a third adhesive layer 300c. The third semiconductor chip 200c may be arranged such that a first surface 212c of a substrate 210c of the third semiconductor chip 200c faces the second semiconductor chip 200b. The third semiconductor chip 200c may be stacked on the second semiconductor chip 200b via third conductive bumps. The third semiconductor chip 200c may be attached on the second semiconductor chip 200b by performing a thermal compression process. The third conductive bumps of the third semiconductor chip 200c may be bonded to second bonding pads 280b of the second semiconductor chip 200b through the thermal compression process. A first bonding pad 230c of the third semiconductor chip 200c may be electrically connected to the second bonding pad 280b of the second semiconductor chip 200b through the third conductive bump. The third adhesive layer 300c may include a non-conductive film (NCF).

In the thermal compression process, the non-conductive film may be liquefied and may have fluidity, and may flow between the third semiconductor chip 200c and the second semiconductor chip 200b. The non-conductive film having fluidity may flow between the third conductive bumps and then may be cured to fill a space between the third conductive bumps. A portion of the cured third adhesive layer 300c may protrude from a side surface of the third semiconductor chip 200c.

Second bump structures 260c having an oval shape may be disposed in diagonal regions that extend from a middle region MR of the third semiconductor chip 200c to four corner portions, respectively. The second bump structure 260c may be arranged such that the long axis Xa of the oval shape extends towards the middle region MR. A ratio (L/D) of the long axis to the short axis of the second bump structure 260c may be at least 1.5.

When the non-conductive film having fluidity flows through the second bump structures 260c along a diagonal direction in the diagonal regions that have relatively long lengths, since the flow resistance coefficient CD of the second bump structure 260c is relatively low compared to the first bump structure, a flow rate of the non-conductive film flowing through the diagonal region may be relatively increased. Accordingly, the time for the non-conductive film to reach from the middle region MR to the corner portions may be reduced, to thereby prevent the non-conductive film from being unfilled in the corner portions.

Similarly, the fourth semiconductor chip 200d may be attached onto the third semiconductor chip 200c using a fourth adhesive layer 300d. The fourth semiconductor chip 200d may be arranged such that a first surface 212d of a substrate 210d of the fourth semiconductor chip 200d faces the third semiconductor chip 200c. The fourth semiconductor chip 200d may be stacked on the third semiconductor chip 200c via fourth conductive bumps. The fourth semiconductor chip 200d may be attached on the third semiconductor chip 200c by performing a thermal compression process. The fourth conductive bumps of the fourth semiconductor chip 200d may be bonded to second bonding pads 280c of the third semiconductor chip 200c through the thermal compression process. A first bonding pad 230d of the fourth semiconductor chip 200d may be electrically connected to the second bonding pad 280d of the third semiconductor chip 200d through the fourth conductive bump. The fourth adhesive layer 300d may include a non-conductive film (NCF).

In the thermal compression process, the non-conductive film may be liquefied and may have fluidity, and may flow between the fourth semiconductor chip 200d and the third semiconductor chip 200c. The non-conductive film having fluidity may flow between the fourth conductive bumps and then may be cured to fill a space between the fourth conductive bumps. A portion of the cured fourth adhesive layer 300d may protrude from a side surface of the fourth semiconductor chip 200d.

Second bump structures 260d having an oval shape may be disposed in diagonal regions that extend from a middle region MR of the fourth semiconductor chip 200d to four corner portions, respectively. The second bump structure 260d may be arranged such that the long axis Xa of the oval shape extends towards the middle region MR. A ratio (L/D) of the long axis to the short axis of the second bump structure 260d may be at least 1.5.

When the non-conductive film having fluidity flows through the second bump structures 260d along a diagonal direction in the diagonal regions that have relatively long lengths, since the flow resistance coefficient CD of the second bump structure 260d is relatively low compared to the first bump structure, a flow rate of the non-conductive film flowing through the diagonal region may be relatively increased. Accordingly, the time for the non-conductive film to reach from the middle region MR to the corner portions may be reduced, to thereby prevent the non-conductive film from being unfilled in the corner portions.

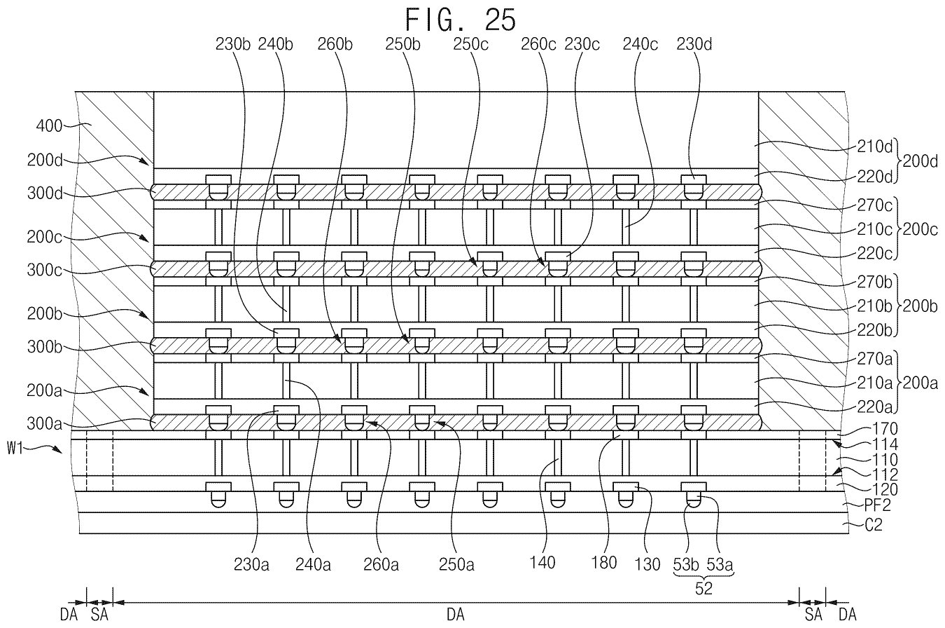

Referring to FIG. 25, a molding member 400 may be formed on the first wafer W1 to cover side surfaces of the first, second, third and fourth semiconductor chips 200a, 200b, 200c and 200d.

In example embodiments, the molding member 400 may be formed to fill gaps between the first, second, third and fourth semiconductor chips 200a, 200b, 200c and 200d. The molding member 400 may expose an upper surface of the fourth semiconductor chip 200d. The molding member 400 may be formed using a polymer material such as an epoxy molding compound (EMC).

Then, the first wafer W1 may be cut along the scribe lane region SA to form a buffer die 100 and the molding member 400 may be cut together to complete the semiconductor package 50 of FIG. 2.

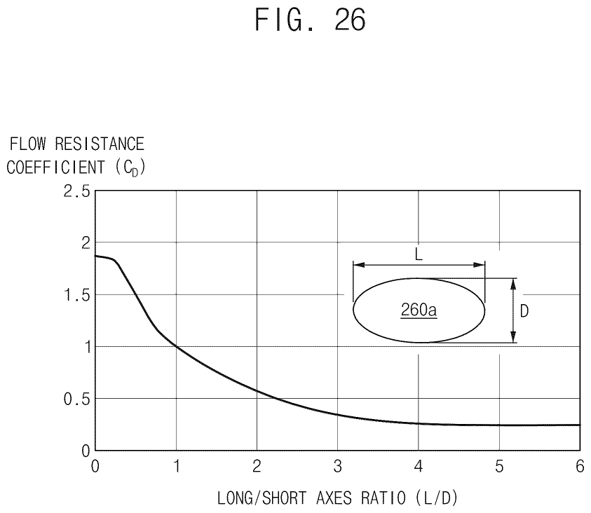

FIG. 26 is a graph showing a change in flow resistance coefficient according to a ratio of long and short axes of a non-conductive film around an oval conductive bump.

Referring to FIG. 26, when a non-conductive film with fluidity flows in a direction parallel to the long axis direction of the oval conductive bump 260a, it can be seen that the flow resistance coefficient (CD) of the oval conductive bump 260a decreases as the long/short axis ratio (L/D) increases. Since a diagonal distance from the center of the chip to the corner of the chip is 1.43 times greater than a longitudinal distance to the edge of the chip, when the flow resistance coefficient (CD) of each of the conductive bumps 260a that are diagonally arranged is less than 0.7, the flow velocity may be 1.43 times faster, allowing the non-conductive film to reach the corner of the chip within the same time. When the long/short axis ratio (L/D) of the oval conductive bump 260a is at least 1.5, it may be possible to prevent the corner portion from being unfilled with the non-conductive film.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a buffer die;
a plurality of core dies sequentially stacked on the buffer die via conductive bumps; and
a plurality of adhesive layers between the plurality of core dies, the plurality of adhesive layers filling spaces between the conductive bumps and interconnecting the plurality of core dies;
wherein each of the core dies of the plurality of core dies comprises a middle region and diagonal regions that extend from the middle region to four corner portions of a respective core die, and
wherein the conductive bumps comprises:
a plurality of first bump structures in the middle region, each first bump structure having a circular shape; and
a plurality of second bump structures in each of the diagonal regions, each second bump structure having an elliptical shape.

2. The semiconductor package of claim 1, wherein the plurality of second bump structures are arranged such that longitudinal axes of the plurality of second bump structures extend toward the middle region.

3. The semiconductor package of claim 1, wherein a ratio of a major axis to a minor axis of each second bump structure of the plurality of second bump structures is at least 1.5, and
wherein the major axis has a first length and the minor axis has a second length shorter than the first length.

4. The semiconductor package of claim 1, wherein each second bump structure of the plurality of second bump structures has a major axis length within a range of 15 μm to 40 μm and a minor axis length within a range of 8 μm to 20 μm, and
wherein the minor axis length is shorter than the major axis length.

5. The semiconductor package of claim 1, wherein each first bump structure of the plurality of first bump structures has a diameter within a range of 10 μm to 20 μm.

6. The semiconductor package of claim 1, wherein each first bump structure of the plurality of first bump structures comprises (i) a first pillar bump having a circular shape on a first bonding pad in the middle region and (ii) a first solder bump on the first pillar bump, and
wherein each second bump structure of the plurality of second bump structures comprises (i) a second pillar bump having an oval shape on a first bonding pad in each of the diagonal regions and (ii) a second solder bump on the second pillar bump.

7. The semiconductor package of claim 6, wherein the first pillar bump of each of the plurality of first bump structures and the second pillar bump of the each of the plurality of second bump structures comprise copper.

8. The semiconductor package of claim 1, wherein a length in an extension direction of each of the diagonal regions from the middle region is within a range of 4 mm to 6.5 mm.

9. The semiconductor package of claim 1, wherein each of the core dies of the plurality of core dies comprises (i) a substrate having a first surface and a second surface opposite to the first surface, and (ii) first bonding pads on the first surface of the substrate.

10. The semiconductor package of claim 1, wherein the plurality of adhesive layers comprise a non-conductive film (NCF).

11. A semiconductor package, comprising:
a first semiconductor chip;
a second semiconductor chip;
a third semiconductor chip;
a fourth semiconductor chip; and
a plurality of adhesive layers,
wherein the first semiconductor chip, the second semiconductor chip, the third semiconductor chip, and the fourth semiconductor chip are sequentially stacked using conductive bumps,
wherein the plurality of adhesive layers are between the first semiconductor chip, the second semiconductor chip, the third semiconductor chip, and the fourth semiconductor chip, the plurality of adhesive layers filling spaces between the conductive bumps and interconnecting the first semiconductor chip, the second semiconductor chip, the third semiconductor chip, and the fourth semiconductor chip,
wherein each of the first semiconductor chip, the second semiconductor chip, the third semiconductor chip, and the fourth semiconductor chip comprises (i) a substrate having a first surface and a second surface opposite to the first surface, and (ii) first bonding pads provided on the first surface of the substrate,
wherein each of the first semiconductor chip, the second semiconductor chip, the third semiconductor chip, and the fourth semiconductor chip has a middle region and diagonal regions that extend from the middle region to four corner portions of a respective semiconductor chip, and
wherein the conductive bumps comprises:
a plurality of first bump structures on the first bonding pads in the middle region, each first bump structure having a circular shape, and
a plurality of second bump structures on the first bonding pads in each of the diagonal regions, each second bump structure having an elliptical shape.

12. The semiconductor package of claim 11, wherein each of the first semiconductor chip, the second semiconductor chip, the third semiconductor chip, and the fourth semiconductor chip comprises through electrodes that penetrate the substrate of a respective semiconductor chip.

13. The semiconductor package of claim 11, wherein the plurality of second bump structures are arranged such that longitudinal axes of the plurality of second bump structures extend toward the middle region.

14. The semiconductor package of claim 11, wherein a ratio of a major axis to a minor axis of each second bump structure of the plurality of second bump structures is at least 1.5, and
wherein the major axis has a first length and the minor axis has a second length shorter than the first length.

15. The semiconductor package of claim 11, wherein each of the plurality of second bump structures has a major axis length within a range of 15 μm to 40 μm and a minor axis length within a range of 8 μm to 20 μm, and
wherein the minor axis length is shorter than the major axis length.

16. The semiconductor package of claim 11, wherein each of the plurality of first bump structures has a diameter within a range of 10 μm to 20 μm.

17. The semiconductor package of claim 11, wherein each of the plurality of first bump structures comprises (i) a first pillar bump having a circular shape on the first bonding pad in the middle region and (ii) a first solder bump on the first pillar bump, and
wherein each of the plurality of second bump structures comprises a second pillar bump having an oval shape on the first bonding pad in each of the diagonal regions and (ii) a second solder bump on the second pillar bump.

18. The semiconductor package of claim 17, wherein the first pillar bump of each of the plurality of first bump structures and the second pillar bump of each of the plurality of second bump structures comprise copper.

19. The semiconductor package of claim 11, wherein the plurality of adhesive layers comprises a non-conductive film (NCF).

20. A semiconductor package, comprising:
a first semiconductor chip comprising (i) a first substrate having a first surface and a second surface opposite the first surface, (ii) a plurality of first through electrodes penetrating the first substrate, and (iii) a plurality of first bonding pads provided on the second surface and electrically connected to the plurality of first through electrodes;
a second semiconductor chip stacked on the second surface of the first semiconductor chip, the second semiconductor chip comprising (i) a second substrate having a third surface that faces the second surface and a fourth surface opposite to the third surface, and (ii) a plurality of second bonding pads on the third surface to respectively correspond to the plurality of first bonding pads;
a plurality of conductive bumps interposed between the plurality of first bonding pads and the corresponding plurality of second bonding pads; and
an adhesive layer between the first semiconductor chip and the second semiconductor chip, the adhesive layer filling spaces between the conductive bumps and interconnecting the first semiconductor chip and the second semiconductor chip,
wherein the second substrate of the second semiconductor chip has diagonal regions that extend from a middle region to four corner portions of the second semiconductor chip,
wherein the plurality of conductive bumps comprise bump structures on the plurality of second bonding pads in each of the diagonal regions, each bump structure having an elliptical shape, and
wherein the bump structures are arranged such that longitudinal axes of the bump structures extend toward the middle region.
